(19) United States
(12) Patent Application Publication
(10) Pub. No.: US 2026/0259289 A1
(43) Pub. Date: Sep. 3, 2026

(54) Real-Time Optimized Sampling Patterns for 3D Accelerated MRI Reconstruction

(71) Applicant: The Board of Trustees of the Leland Stanford Junior University, Stanford, CA (US)

(72) Inventors: Jaehyeok Bae, Stanford, CA (US); Cagan Alkan, Redwood City, CA (US); Kawin Setsompop, Stanford, CA (US); John M. Pauly, Stanford, CA (US)

(21) Appl. No.: 19/555,608

(22) Filed: Mar. 3, 2026

Related U.S. Application Data
(60) Provisional application No. 63/766,254, filed on Mar. 3, 2025.

(51) Int. Cl. G01R 33/48; G01R 33/561

(52) U.S. Cl. CPC G01R 33/4826; G01R 33/5611

(57) ABSTRACT

A method for magnetic resonance imaging includes generating a sampling pattern; acquiring k-space data during an MRI scan using the generated sampling pattern; and reconstructing an MRI image from the acquired k-space data. The sampling pattern is generated by storing a variable-density model of k-space based on Voronoi-cell statistics extracted from a set of optimized sampling patterns; receiving one or more acquisition parameters for a target MRI scan, the acquisition parameters including at least a target acceleration rate; calculating a target sampling density across k-space by applying the variable-density model to the one or more acquisition parameters; and generating a sampling pattern in real-time based on the target sampling density such that the target acceleration rate is achieved.

### CROSS-REFERENCE TO RELATED APPLICATIONS

This application claims priority from U.S. Provisional Patent Application 63/766,254 filed Mar. 3, 2025, which is incorporated herein by reference.

### STATEMENT OF FEDERALLY SPONSORED RESEARCH

This invention was made with Government support under contract EB029427, EB036127, MH116173 awarded by the National Institutes of Health. The Government has certain rights in the invention.

### FIELD OF THE INVENTION

The present invention relates generally to magnetic resonance imaging (MRI). More specifically, it relates to techniques for optimizing k-space sampling patterns to enable accelerated MRI acquisitions.

### BACKGROUND OF THE INVENTION

Accelerated MRI acquisition often relies on under-sampling k-space data, where only a fraction of the raw data required to satisfy the Nyquist-Shannon sampling criterion is collected. In an MRI scan, a sampling pattern determines which data points in k-space are acquired during the acquisition. Sampling pattern optimization techniques seek to reduce scan time by strategically selecting a sampling pattern, without sacrificing image quality. Two examples of existing methods for MRI sampling pattern optimization are AutoSamp and Variable density (VD) Poisson Disc.

VD Poisson Disc, a traditional method for generating variable-density sampling patterns, is straightforward to implement but suffers from clustering artifacts and provides suboptimal reconstruction quality compared to more recent approaches.

AutoSamp is a deep learning-based method that jointly optimizes sampling patterns and reconstruction networks, enabling high-quality image reconstruction. However, the optimization demands significant computational resources and requires retraining whenever scanning parameters change, limiting its practicality for real-time clinical settings. This combination of high complexity and limited flexibility poses a significant barrier to widespread adoption in both clinical and research applications.

### SUMMARY OF THE INVENTION

Herein is disclosed a method and system for the real-time generation of optimized k-space sampling patterns for accelerated MRI. This heuristic-based framework removes the need for retraining and enables real-time, efficient sampling pattern generation. It delivers reconstruction quality comparable to AutoSamp without the associated computational burdens, and it significantly outperforms VD Poisson Disc by ensuring uniform sampling and minimizing clustering artifacts. It also eliminates the need for extensive computational retraining. It allows for fast and adaptable generation of hexagonal sampling patterns optimized in real time for specific scanning parameters, which may include acceleration rates, coil configurations, and subject anatomical information from a scout scan. This shift from joint optimization to a heuristic-driven approach achieves reconstruction quality on par with state-of-the-art methods while significantly reducing complexity and resource requirements. This innovation provides a practical, adaptable solution suitable for both clinical and research applications.

The present approach to generating MRI sampling patterns parameterizes Voronoi cell area distributions that have been derived from state-of-the-art sampling optimization methods, such as AutoSamp. It generates hexagonal sampling patterns optimized for specific scanning parameters such as acceleration rates and coil configurations. In some implementations, Voronoi cell areas are modeled as piecewise linear functions based on acceleration factors and coil configurations. Adjustable parameters such as the minimum Voronoi area and noise level introduce controlled randomness, allowing fine-tuning for specific imaging requirements. A hexagonal sampling pattern is constructed in some embodiments using a Breadth-First Search (BFS) algorithm, starting from the center of k-space and expanding outward. This approach ensures that the pattern adheres to Voronoi cell area criteria while maintaining uniformity and efficiency.

In some embodiments, the sampling pattern is generated based on a model that parameterizes Voronoi-cell statistics as a function of radial distance in k-space. The model may be further parameterized by scan-specific acquisition settings, such as a target acceleration rate and a number of virtual coils.

In other embodiments, the sampling pattern is generated based on a subject-specific model that incorporates anatomical information acquired from a scout scan. In such implementations, the model may estimate the spatial support and anisotropy of a subject to derive an anisotropy-aware target density. This density is then used to instantiate an asymmetric sampling mask, which may be tailored to the specific dimensions of the subject's anatomy.

According to various aspects, the generated sampling patterns may comprise hexagonal or variable-density Controlled Aliasing in Parallel Imaging (VD-CAIPI) compatible lattices. By providing a simplified geometric framework for sampling optimization, the disclosed methods enable high-quality image reconstruction across diverse hardware configurations and patient anatomies while reducing the computational overhead associated with conventional optimization techniques.

The present technique enables real-time dynamic sampling pattern generation for commercial MRI systems, supports the creation of research tools for testing and developing MRI acquisition strategies without extensive computational demands, and enhances clinical imaging workflows for efficient, high-quality accelerated MRI. It also has potential applications in dynamic sampling, where optimal patterns can be adaptively generated in real time based on previous reconstruction results.

In one aspect, the invention provides a method for magnetic resonance imaging comprising: generating a sampling pattern; acquiring k-space data during an MRI scan using the generated sampling pattern; and reconstructing an MRI image from the acquired k-space data. Generating the sampling pattern comprises: storing a variable-density model of k-space based on Voronoi-cell statistics extracted from a set of optimized sampling patterns; receiving one or more acquisition parameters for a target MRI scan, the acquisition parameters including at least a target acceleration rate; calculating a target sampling density across k-space by applying the variable-density model to the one or more acquisition parameters; and generating a sampling pattern in real-time based on the target sampling density such that the target acceleration rate is achieved.

In one embodiment, the variable-density model comprises a piecewise linear model as a function of radial distance in k-space that is fit with Veronoi cell areas of the optimized sampling pattern. The acquisition parameters may further include a number of virtual coils. Generating the sampling pattern may include sequentially constructing neighboring hexagonal points via a Breadth-First Search (BFS) until the target acceleration rate is met.

In another embodiment, the method further includes acquiring a scout image of a subject prior to generating the sampling pattern. The method may further include estimating a spatial-support width and height of the subject from the scout image, wherein the acquisition parameters include the estimated spatial-support. The variable-density model may account for anatomical-shape-anisotropy by determining Voronoi-cell-length profiles along each phase-encoding k-space axis. The generated sampling pattern may be an asymmetric, VD-CAIPI-compatible hexagonal mask.

### BRIEF DESCRIPTION OF THE DRAWINGS

FIG. 1 is a processing pipeline illustrating the processing pipeline for an MRI scan, according to an embodiment of the invention.

FIG. 2 shows details of sampling pattern generation step 104 of FIG. 1.

FIG. 3 is a visualization of the process for generating a sampling pattern according to a first embodiment of the invention.

FIG. 4A shows an overview of a second embodiment of the invention.

FIG. 4B shows further details of the second embodiment of the invention.

FIG. 5 illustrates intermediate-R interpolation, according to an embodiment of the invention.

### DETAILED DESCRIPTION OF THE INVENTION

The following description is directed to systems and methods for accelerated magnetic resonance imaging including generating in real time optimized k-space sampling patterns. The sampling pattern generation framework described herein distills complex, data-driven optimization results into interpretable geometric models, specifically utilizing Voronoi-cell parameterization to define sampling densities.

In a 3D acquisition scenario, the readout axis (kₓ) is typically fully sampled, while the phase-encoding axes (k_{y}, k_{z}) are undersampled by an acceleration factor R. The imaging system is represented by a forward model where the acquired k-space data is a function of the image, the sampling mask, coil sensitivities, and measurement noise. The methods disclosed herein aim to define the sampling mask φ in real-time to maximize reconstruction quality for a given R.

The disclosed embodiments use models derived from extracted geometric statistics of optimized sampling patterns (i.e., sampling patterns optimized via a joint-optimization framework such as AutoSamp). By modeling the geometric properties of Voronoi cells—defined as the regions of k-space closer to a given sampling point than any other point—the system can calculate in real time an ideal sampling density for new scanning parameters.

### Processing Pipeline Overview

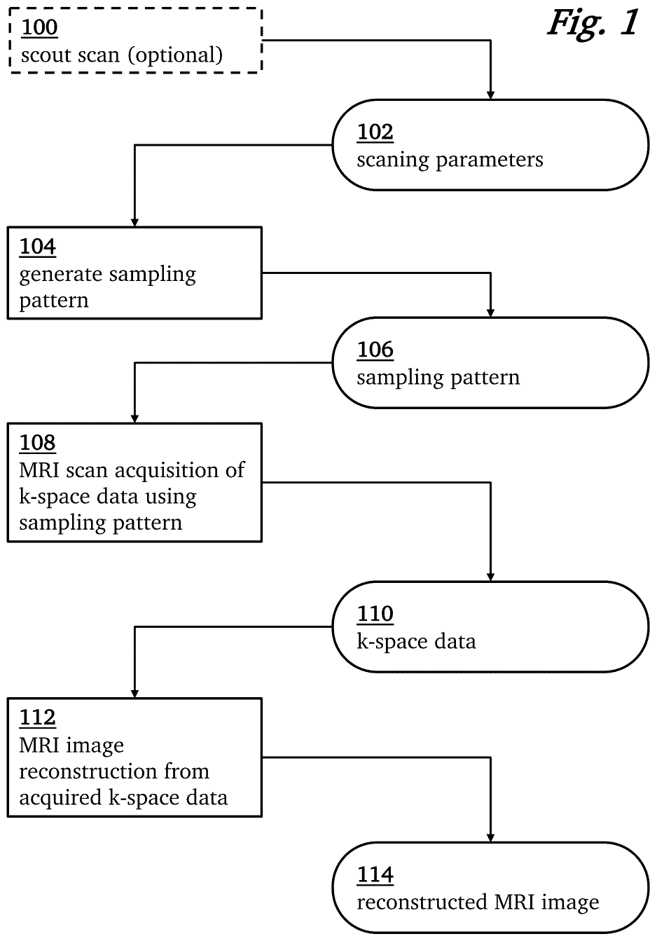

FIG. 1 is a processing pipeline illustrating the processing pipeline for an MRI scan, according to an embodiment of the invention.

Step 104 generates in real time a sampling pattern 106 for MRI acquisition. The sampling pattern 106 is optimally generated in real time based on specific scanning parameters 102 of a current scan, which may include a desired acceleration rate, hardware configurations (coil count), or subject-specific metadata (anatomical support from an optional scout scan 100). The sampling pattern generation 104 uses a predetermined model that has been previously extracted off-line based on statistical trends derived from a set of optimized sampling patterns (e.g., AutoSamp-optimized patterns). Step 108 performs an MRI scan, including an acquisition of k-space data 110 using the sampling pattern 106. In step 112, the k-space data 110 is processed to produce a reconstructed MRI image 114.

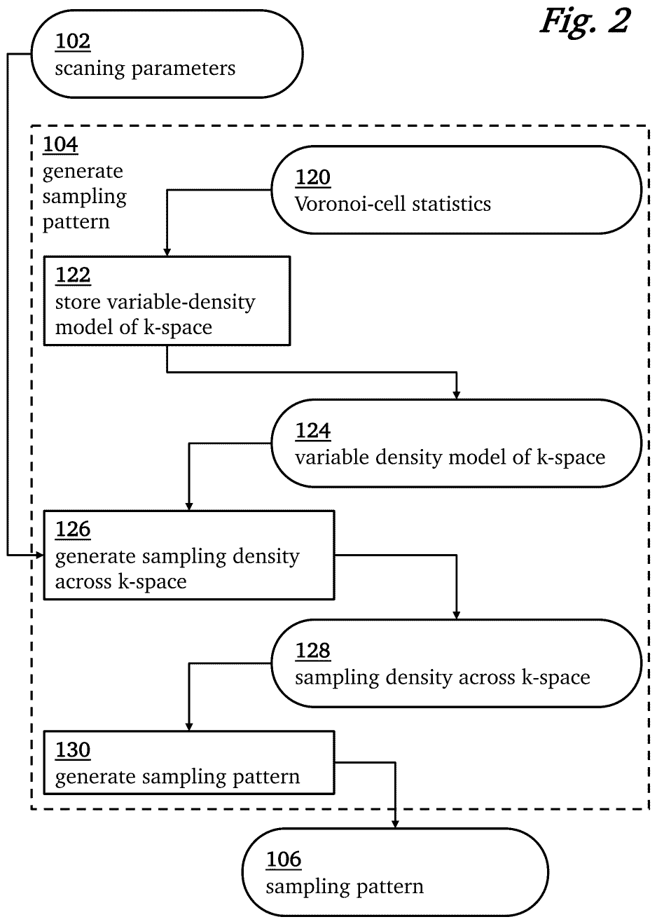

Further details of sampling pattern generation step 104 are shown FIG. 2. In step 122 a variable-density model of k-space 124 is defined based on Voronoi-cell statistics 120 that have been previously extracted in an off-line process from a set of optimized sampling patterns. In the variable-density model 124, the geometric properties of the Voronoi cells—either their area or length—are parameterized as functions of k-space coordinates or radial distance. In one embodiment, Voronoi-cell statistics (area and/or length) are extracted from AutoSamp-optimized patterns and modeled with piecewise linear equations. The model is derived by extracting trends from AutoSamp, a complex deep-learning framework that jointly optimizes sampling and reconstruction. The variable-density model is dependent on the dataset and scanner, and it is trained from a large dataset, which is a set of previous scans. Preferably, step 122, which defines the variable-density model of k-space 124, is performed for each scanner by the manufacturer before each scanner is set up.

In step 126, the parameterized Voronoi model 124 is applied to the scanning acquisition parameters 102 to calculate in real time a target sampling density distribution 128 across k-space. This involves determining how the spacing between sampling points should vary to satisfy the required acceleration while maintaining image quality. The calculation of the target sampling density distribution 128 is performed through computationally efficient linear fits and interpolation between reference profiles, based on the scanning parameters 102. The scanning parameters 102 are input parameters such as a desired acquisition acceleration rate, scanner virtual coil counts, and/or subject-specific spatial support derived from a scout scan.

In step 130, a sampling pattern mask 106 is generated in real-time based on the calculated sampling density profile 128. This may be achieved through an iterative or algorithmic process, such as Breadth-First Search (BFS) or mapping a VD-CAIPI-compatible lattice, until the specified target acceleration rate is satisfied. The sampling pattern 106 is a hexagonal or VD-CAIPI-compatible mask.

### QuickSamp

In one embodiment, referred to as QuickSamp, we derive sampling patterns from AutoSamp pattern statistics without requiring additional training yet maintaining high reconstruction quality. We parameterize the Voronoi cell area distribution of AutoSamp patterns into piecewise linear forms (models) to create radial hexagonal sampling patterns. In addition, by examining AutoSamp patterns, we are able to extract interpretable trends for parameterizing the sampling with different acceleration rates and coil configurations.

The Voronoi-cell-area distribution of optimized sampling patterns is modeled using a piecewise linear form as a function of the radial distance (kᵣ) from the k-space center. The model defines a minimum Voronoi cell area at the center, which increases linearly to a threshold αₜ=mₜα₀ at a specific radial distance rₜ. Beyond rₜ, the area remains constant at αₜ.

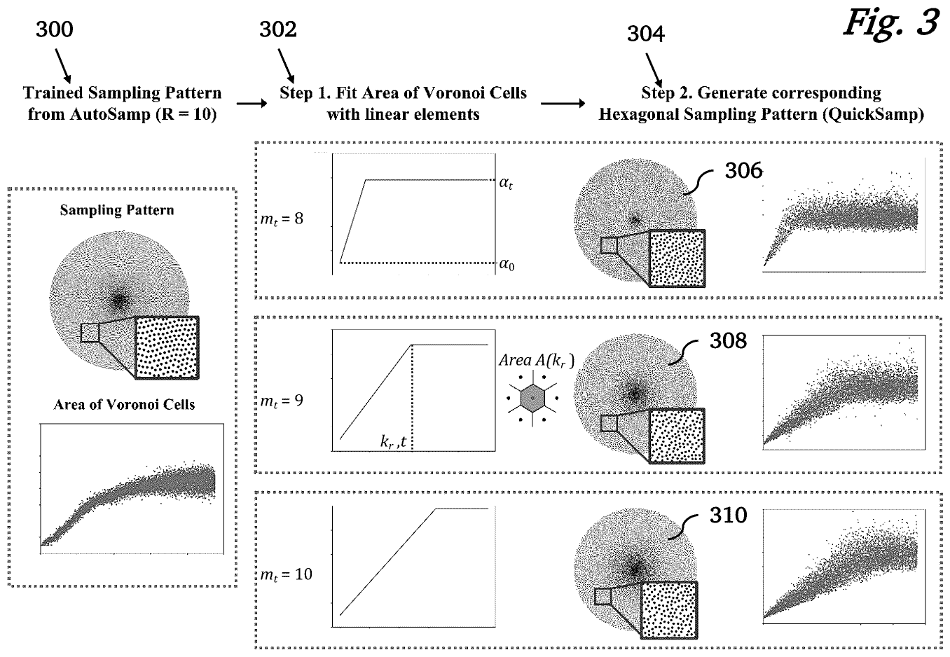

FIG. 3 is a visualization of the process for generating our QuickSamp pattern. First, the Voronoi cell area distribution of AutoSamp 300 is modeled with linear elements in step 302. The model is parameterized by the area threshold αₜ=mₜα₀ and noise level η. Next, Breadth-First Search (BFS) is applied to construct the corresponding hexagonal sampling pattern in step 304. Starting from the center, neighboring hexagonal points are sequentially added that meet the Voronoi area criteria until the desired acceleration rate R is achieved. The figure illustrates various hexagonal patterns 306, 308, 310, generated from different values of mₜ at an acceleration rate of R=10. The parameters mₜ and a noise level η are derived through heuristic equations that account for the target acceleration rate R and the number of virtual coils C. For example, as the number of coils decreases, the model sets parameters to create a pattern that is denser near the k-space center with increased randomness at higher frequencies.

We now discuss details of strategies for modeling sampling patterns. We consider 3D-scenario where readout axis (kₓ) is fully-sampled and phase-encoding axes (k_{y}, k_{z}) are under-sampled by R. The forward model is

$$z = {f}_{ϕ} ( x ) + ϵ = [ \begin{matrix}\begin{matrix}{F}_{nu} ( ϕ ) {S}_{1} \\ ⋮\end{matrix} \\ {F}_{nu} ( ϕ ) {S}_{C}\end{matrix} ] x + ϵ$$

where z∈ [symbol] ^{M} is the k-space data, x∈ [symbol] ^{N} is the image, f_{φ}(⋅) represents the imaging system described by φ∈[−0.5, 0.5]^{M}, ϵ∈N_{C} (0, σ²I) is the measurement noise, and C is the number of channels.

The AutoSamp joint-optimization minimizes:

$${}_{ϕ , θ}^{max} ℒ ( ϕ , θ ; D ) = {}_{ϕ , θ}^{max} {Σ}_{x ∈ D} {E}_{q ϕ ( Z \vert x )} [ log {p}_{θ} ( x \vert z ) ]$$

where θ denotes the parameters of the reconstruction network and D is the dataset. Patterns optimized by AutoSamp resemble hexagonal pattern and show dependencies on acceleration factor, noise level and coil sensitivity.

In this embodiment, we model φ as parameterized hexagonal sampling and train θ with the fixed φ. As discussed above, we derive QuickSamp pattern by fitting the Voronoi-cell-area of AutoSamp's sampling with a segmented line model.

The minimum Voronoi cell area is set to

$${α}_{0} = \frac{1}{F O {V}^{2}} .$$

We introduce two parameters: a threshold αₜ=mₜα₀, where mₜ≥1 is adjustable, and a noise level η∈[0, 1] to introduce controlled randomness to the sampling. The radial distance where two lines meet, rₜ, is calculated from αₜ and R. In the low frequency region (r<rₜ), Voronoi cell area A(r) linearly increases from α₀ to αₜ. In the high frequency region (r>rₜ), A(r) is constant on αₜ.

Using these parameters, we generate sampling points via Breadth-First Search (BFS). Starting from the center (0, 0), we sequentially make neighboring hexagonal points that meet the Voronoi area criteria until the desired acceleration rate R is achieved.

The AutoSamp patterns are dependent on acceleration rate R and the number of virtual coils C. By examining the statistics of the patterns, a heuristic equation of optimized parameters mₜ and η is derived:

$${m}_{t} = A \times R \times {( \frac{c}{{c}_{0}} )}^{γ}$$

$$η = 1 - \frac{c}{{c}_{0}}$$

where A is a dataset-specific constant, and C₀ is the default number of coils. For the Stanford 3D-FSE Knee dataset, we used A=0.9, γ=−0.15, and C₀=8 as default values.

We used “Stanford Fully-Sampled 3D-FSE Knees” dataset, acquired with matrix-size=320×320×256 and 8-chn array. We applied Fourier-Transform along kₓ and treated each x-slice as separate images. Coil-sensitivities were estimated via ESPIRiT. We used 14 subjects (4480 slices) for training, 2 subject (640 slices) for validation, and 3 subject (960 slices) for testing.

### AdaSamp

In another embodiment, referred to as AdaSamp, the system adapts the sampling pattern to the specific anatomy of the subject being scanned. AdaSamp generates simple, subject-specific sampling-mask guided by a fast scout image and tailors k-space coverage to each patient's spatial-support and anisotropy. It outperforms population-based sampling-masks in reconstruction quality and streamlines practical deployment of subject-adaptive 3D-MRI across diverse anatomies. On retrospectively undersampled 3D-knee enriched with knee-size scalings/deformations, AdaSamp surpasses AutoSamp in PSNR/SSIM and, at matched image quality, enables higher R (shorter scans). On 3D-brain with latent-diffusion reconstruction, it outperforms variable-density Poisson-disc in reconstruction quality.

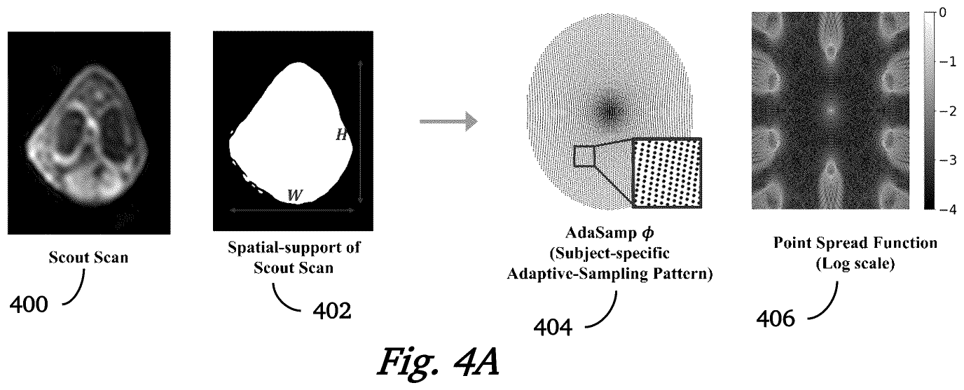

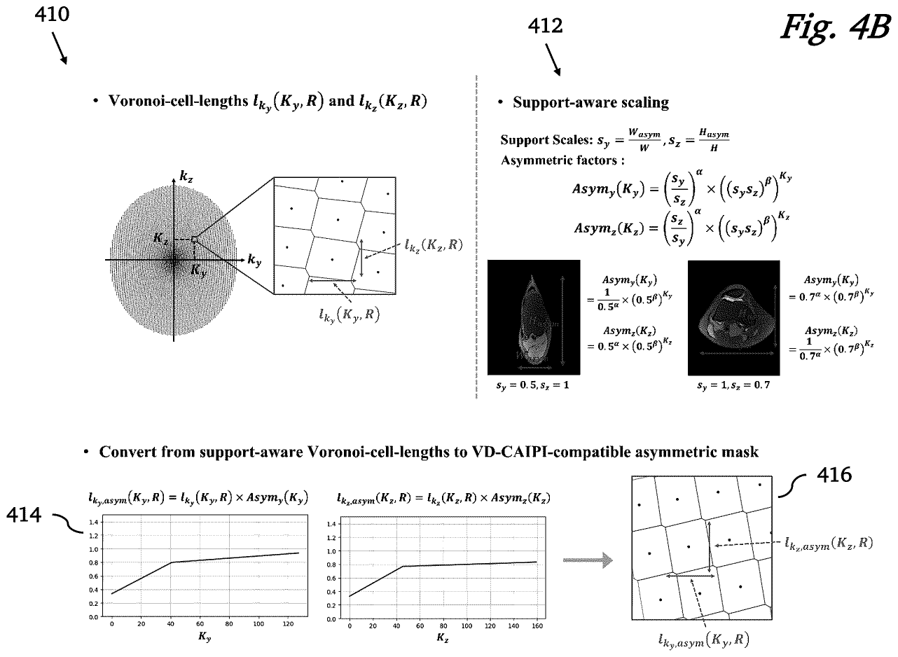

FIG. 4A shows an overview of the embodiment. From a rapid scout image 400, we estimate support 402 and parameterize sampling-mask's Voronoi-cell-length versus k-space radial-distance along each k-space axis to define an anisotropic density model. From this we generate a VD-CAIPI-compatible asymmetric sampling-mask 404 with the designed density and target acceleration R. The sampling mask is a VD-CAIPI asymmetric hex mask. The Point Spread Function 406 shows controlled sidelobes. FIG. 4B shows further details of the process, specifically building of directional Voronoi-cell-length profiles 410, and application of support-aware scaling (s_{y}, s_{z}) to obtain support-aware profiles 412. The Voronoi-cell-length ( [symbol] _{ky}, [symbol] _{kz}) is parameterized along each phase-encoding axis independently to account for anatomical-shape-anisotropy. Spatial-support scales (s_{y}, s_{z}) and asymmetric factors (α, β) are calculated to define the support-aware profiles. These profiles adjust the sampling density by applying an outward radial shift for shrunk axes and anisotropic reweighting. The support-aware profiles 414 are mapped to density and lattice spacings to yield a subject-specific VD-CAIPI-compatible asymmetric mask 416, where the k-space coverage is tailored to the patient's unique spatial support.

This embodiment also allows for the generation of masks at intermediate acceleration rates not present in the optimized sampling pattern training set. By interpolating between Voronoi-length profiles learned at reference accelerations (e.g., R=5 and R=10), the system can synthesize an optimized mask for any unseen R without retraining. Additionally, the subject-specific nature of the model enables “iso-quality”acceleration, where the maximum R is adaptively selected for each subject to meet a target reconstruction quality (e.g., a specific PSNR), thereby reducing scan times for subjects with smaller anatomical supports.

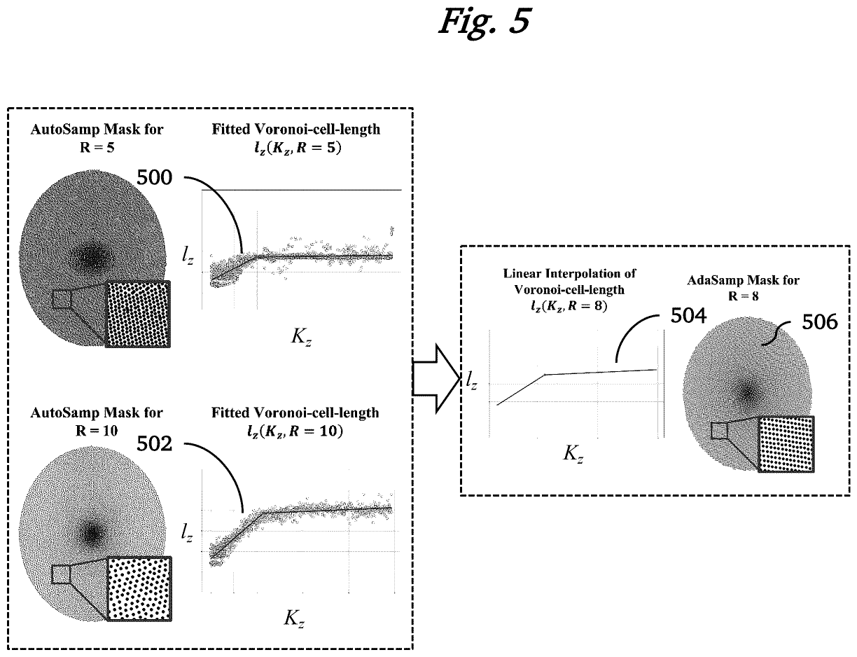

FIG. 5 illustrates intermediate-R AdaSamp via interpolation. Directional Voronoi-cell-length profiles 500, 502 learned from AutoSamp at reference accelerations (R=5, 10) are interpolated 504 to synthesize a mask 506 at an unseen rate (R=8) without retraining. The resulting AdaSamp mask produces constructions that surpass variable-density Poisson-disc while remaining comparable to AutoSamp.

We now discuss further details of AdaSamp. We consider a 3D-acquisition with fully sampled kₓ and undersampled (k_{y}, k_{z}) by acceleration R. Let x∈ [symbol] ^{N} be the image and S_{C} coil-sensitivities. With a sampling-mask φ and non-uniform FFT Fₙᵤ(φ), the forward model is

$$z = {f}_{ϕ} ( x ) + ϵ = [ \begin{matrix}\begin{matrix}{F}_{nu} ( ϕ ) {S}_{1} \\ ⋮\end{matrix} \\ {F}_{nu} ( ϕ ) {S}_{C}\end{matrix} ] x + ϵ , ϵ ∈ {N}_{C} ( 0 , {σ}^{2} I )$$

AutoSamp jointly optimizes φ and a reconstruction network θ by maximizing the expected data-conditional log-likelihood over a dataset D:

$${}_{ϕ , θ}^{max} ℒ ( ϕ , θ ; D ) = {}_{ϕ , θ}^{max} {Σ}_{x ∈ D} {E}_{q ϕ ( Z \vert x )} [ log {p}_{θ} ( x \vert z ) ]$$

The resulting masks are typically hexagonal and vary systematically with R.

From a rapid scout, we estimate the width/height (W,H) of the subject's spatial-support. Using the support profile and target R, we derive an anisotropy-aware target density and instantiate a VD-CAIPI-compatible asymmetric sampling mask. Voronoi-cell-length is the mean Voronoi edge-length (per k-space-axis) varying with k-space coordinates (K_{y}, K_{z}) and R, represented as:

lₖ_{_{y}}(K_{y},R),lₖ_{_{z}}(K_{z},R).

From AutoSamp-optimized masks, the baselines lₖ_{_{y}}, lₖ_{_{z}} are extracted via a piecewise-linear fits along (K_{y}, K_{z}). For anisotropic spatial-support with effective width/height (W_{asym}, H_{asym}), we define spatial-support scales:

$${s}_{y} = \frac{{W}_{a s y m}}{W} , {s}_{z} = \frac{{H}_{a s y m}}{H} .$$

From AutoSamp masks trained on synthesized data with synthetic anisotropic supports (independent y, z deformations by ratios s_{y}, s_{z}∈(0, 1], 1=no shrinkage), we observe two effects of support shrinkage: (i) an outward radial shift (shorter cells at high frequency, longer at low) and (ii) anisotropic reweighting toward the more-shrunk axis. We capture both via multiplicative factors:

$${Asym}_{y} ( {K}_{y} ) = {( \frac{{s}_{y}}{{s}_{z}} )}^{α} \times {( {( {s}_{y} {s}_{z} )}^{β} )}^{{K}_{y}} ,$$

$${Asym}_{z} ( {K}_{z} ) = {( \frac{{s}_{z}}{{s}_{y}} )}^{α} \times {( {( {s}_{y} {s}_{z} )}^{β} )}^{{K}_{z}} ,$$

and define support-aware profiles:

$${l}_{{k}_{y} , asym} ( {K}_{y} , R ) = {l}_{{k}_{y}} ( {K}_{y} , R ) \times {Asym}_{y} ( {K}_{y} )$$

$${l}_{{k}_{z} , asym} ( {K}_{z} , R ) = {l}_{{k}_{z}} ( {K}_{z} , R ) \times {Asym}_{z} ( {K}_{z} ) .$$

Here, α controls the directional reweighting via s_{y}/s_{z}; β controls the radial shift via total area change s_{y}s_{z}. From these profiles, we generate a subject-specific VD-CAIPI asymmetric mask.

For the knee, we used the Stanford Fully-Sampled 3D-FSE Knees dataset. A 1D-FFT is applied along kₓ; each x-slice is reconstructed independently. Splits: (14, 2, 3) subjects for train, validation, and test, respectively. For synthesized data, synthetic anisotropy uses per-subject axis-wise scaling in [0.5, 1.0]. One subject-specific sampling-mask is used across all x-slices for that subject. For the brain, we used the Stanford Longitudinally Accelerated MRI test dataset, fully-sampled 2D-T2-coronal subset. Reconstructions use a pretrained latent-diffusion model¹¹. We compare AdaSamp to variable-density Poisson-disc at (R=20, 30), approximating masks a 2× Fourier-oversampled grid to simplify diffusion inference. We report PSNR/SSIM over 20 slices from 6 subjects.

In conclusion, AdaSamp converts a rapid scout (e.g. coil-sensitivity scan) into an anisotropy-aware target density and instantiates a VD-CAIPI asymmetric sampling-mask in real time. From the scout, AdaSamp estimates object support and leverages Voronoi-cell-length versus k-space radial-distance (per k-space-axis) distilled from AutoSamp trends to set the sampling-lattice parameters. AdaSamp can generate high-quality sampling-masks at intermediate acceleration rates not covered in AutoSamp's training cases. On 3D FSE knee dataset synthesized with per-subject knee-size's scaling/deformation, AdaSamp exceeds AutoSamp at a fixed acceleration rate. Also, AdaSamp allows a variable-acceleration-rate-prescription across subjects at matched reconstruction quality (higher acceleration for easier subjects), to provide across-population scan time reduction. On 3D brain dataset with a pretrained latent-diffusion reconstruction, AdaSamp outperforms variable-density Poisson-disc, indicating reconstruction-agnostic benefits.

1. A method for magnetic resonance imaging comprising:
a) generating a sampling pattern;
b) acquiring k-space data during an MRI scan using the generated sampling pattern; and
c) reconstructing an MRI image from the acquired k-space data;
wherein generating the sampling pattern comprises:
i) storing a variable-density model of k-space based on Voronoi-cell statistics extracted from a set of optimized sampling patterns;
ii) receiving one or more acquisition parameters for a target MRI scan, the acquisition parameters including at least a target acceleration rate;
iii) calculating a target sampling density across k-space by applying the variable-density model to the one or more acquisition parameters; and
iv) generating a sampling pattern in real-time based on the target sampling density such that the target acceleration rate is achieved.

2. The method of claim 1, wherein the variable-density model comprises a piecewise linear model as a function of radial distance in k-space that is fit with Veronoi cell areas of the optimized sampling pattern.

3. The method of claim 1, wherein the acquisition parameters further include a number of virtual coils.

4. The method of claim 1, wherein generating the sampling pattern comprises sequentially constructing neighboring hexagonal points via a Breadth-First Search (BFS) until the target acceleration rate is met.

5. The method of claim 1, further comprising acquiring a scout image of a subject prior to generating the sampling pattern.

6. The method of claim 5, further comprising estimating a spatial-support width and height of the subject from the scout image, wherein the acquisition parameters include the estimated spatial-support.

7. The method of claim 1, wherein the variable-density model accounts for anatomical-shape-anisotropy by determining Voronoi-cell-length profiles along each phase-encoding k-space axis.

8. The method of claim 1, wherein the generated sampling pattern is an asymmetric, VD-CAIPI-compatible hexagonal mask.
